(19) United States
(12) Patent Application Publication
(10) Pub. No.: US 2015/0211106 A1
(43) Pub. Date: Jul. 30, 2015

(54) APPARATUS FOR DEPOSITING THIN FILMS OF ORGANIC MATERIALS

(71) Applicant: Areesys Corporation, Fremont, CA (US)

(72) Inventors: Kai-An Wang, Cupertino, CA (US); Jingru Sun, San Jose, CA (US); Michael Wong, Castro Valley, CA (US)

(21) Appl. No.: 14/589,137

(22) Filed: Jan. 5, 2015

Related U.S. Application Data
(60) Provisional application No. 61/933,310, filed on Jan. 30, 2014.

(51) Int. Cl. C23C 14/26; C23C 14/54

(52) U.S. Cl. CPC C23C 14/26; C23C 14/54

(57) ABSTRACT

A flash deposition apparatus includes a liquid delivery system configured to produce fine liquid droplets of an organic material, a heater configured to vaporize the fine liquid droplets to produce a vapor material to be directed to a substrate on which the organic material is deposited; and a radiation shield configured to shield the heater from the liquid delivery system.

### BACKGROUND OF THE INVENTION

The present application relates to materials deposition technologies, and more specifically to deposition of organic materials.

Conventional thin film deposition systems for organic materials often employ a point or linear thermal evaporation source that is constructed as a crucible. Examples of the organic materials include monomers, oligomers, precursors, polymers or other raw materials. In the conventional evaporation process, the organic materials are heated and held in the crucibles at elevated temperatures for prolonged time (hours to weeks) before they are deposited onto substrates. The organic materials are often heated unevenly in the conventional crucibles which cause process drift from ideal conditions. The lack of accurate process control results in composition variations in the deposited films, and degradation or decomposition of organic materials. During fabrication of organic light-emitting diode (OLED), for instance, it has been proven that extended heating of organic materials in crucibles before evaporation is responsible for shortened lifetimes of OLED devices.

Referring to FIG. 1, a conventional organic thin film deposition system 100 includes a vacuum chamber 170 and a conventional crucible 130 used to contain an organic material 180. An electrical resistive heating element 140 is helicoidally wound around outer surface of the crucible 130. The crucible 130 is partially enclosed by a heat shield 120 having an opening 125. A substrate 110 is positioned with its deposition surface facing towards the opening 125. The organic material 180 is heated to above its evaporation point by the electrical resistive heating element 140 to produce a vaporized material 185. The vaporized material 185 passes through the opening 125 in the heat shield 120, and condenses to form a thin film on the deposition surface of the substrate 110. A vacuum pump 150 is regulated by a valve 160 and is configured to exhaust in the vacuum chamber 170 to maintain a controlled vacuum environment in the vacuum chamber 170.

One challenge in conventional thin film deposition is that the organic materials are often unstable at high temperatures. Another drawback in conventional crucible is that the heating of bulk organic materials is often non-uniform. Furthermore, conventional thin film deposition systems cannot evaporate a mixture of materials with different evaporation temperatures in a controlled manner to maintain desired composition in the deposited film.

Another major drawback with conventional evaporation apparatus is that they heat bulk materials for a long time and waste large amounts of materials during evaporation preparation (i.e. “warm-up” or “seasoning”). The unused portion of the already loaded materials during process ramp-down (“wind-down”) is usually degraded by overheating and has to be discarded. The evaporation preparation and material removal also waste time and energy which results in lower productivity for production equipment.

There is therefore a need for an improved thin film deposition apparatus, which can avoid prolonged or uneven heating of organic materials in the evaporation process and also enable evaporating a range of mixed materials with different evaporation temperatures.

### SUMMARY OF THE INVENTION

The present application discloses a thin film deposition apparatus that can overcome above described problems in conventional organic thin film deposition systems. The disclosed deposition apparatus can eliminate prolonged, undesired overheating of thin film materials, and can prevent degradation, decomposition, or undesirable reactions of organic materials caused by overheating.

The disclosed deposition apparatus can heat and evaporate material more evenly and uniformly than conventional crucible-based deposition systems. The liquid materials are delivered in small droplets and are evaporated in the evaporation heating region instantaneously, which enables more uniform thin film deposition on the substrate for improved thickness control.

The disclosed deposition apparatus allows mixing of different materials with similar or different vaporization temperatures in thin film deposition by simultaneously flash evaporating different organic materials.

The disclosed organic material thin film deposition apparatus features high materials utilization. Unlike conventional technology, the disclosed system does not heat bulk organic materials at elevated temperatures for a long period of time inside crucibles. Instead, the deposition material is delivered, and flash evaporated in amount as needed. As a result, there is very little material, energy, or time waste in the disclosed deposition system.

The disclosed evaporation apparatus can control evaporation temperature precisely and tightly which is as described above critical for thin film deposition of organic materials. Since organic materials delivered to evaporation heaters are in small droplets, the temperatures of evaporation heaters (of much larger heat mass) can be hardly impacted; therefore, organic materials can all be evaporated at precisely and tightly controlled temperatures. This feature in turn ensures well controlled composition in the deposited thin films.

The disclosed apparatus can deposit thin films with better control of thickness and uniformity since a desired small amount of material is delivered by an individual micro pump. The total amount of material can be controlled by pumping frequency, duration of the electric pulse, waveform of the pulse and pumping counts, etc. The deposited thin films can be much thinned than those made by conventional liquid dispensing, wet method, spray-on or spin-on deposition technologies.

Furthermore, the miniature flash evaporation sources are modularized. The disclosed deposition apparatus is scalable in design to process substrates from small to very large sizes.

The disclosed apparatus can also enable flexible orientation of source and substrates which is otherwise not feasible with conventional crucible-based evaporation technologies. In the disclosed deposition apparatus, the substrate can be placed on one side of the deposition source and moving horizontally or vertically, a substrate placed under or on top of the deposition source and moving horizontally.

In one general aspect, the present invention relates to a flash deposition apparatus that includes a liquid delivery system configured to produce fine liquid droplets of an organic material; a heater configured to vaporize the fine liquid droplets to produce a vapor material to be directed to a substrate on which the organic material is deposited; and a radiation shield configured to shield the heater from the liquid delivery system.

Implementations of the system may include one or more of the following. The radiation shield can include a baffle and one or more holes in the baffle, wherein the one or more holes are configured to allow the fine liquid droplets to move to a vicinity of the heater. The radiation shield can block migration of the vapor material toward the liquid delivery system. The radiation shield can include nested enclosure walls which shield the heater at least partially from the liquid delivery system. The nested enclosure walls can shield the heater at least partially from the substrate. The radiation shield can include multiple parallel baffles each comprising one or more holes configured to allow the fine liquid droplets to move to a vicinity of the heater. The flash deposition apparatus can further include a shower head comprising a plurality of holes configured to direct the vapor material to the substrate. The heater can include an oil bath heated at a predetermined elevated temperature. The liquid delivery system can include: a pressure controlled chamber; a reservoir in the pressure controlled chamber and configured to contain a liquid of the organic material; and a liquid material delivering device in fluidic communication with the reservoir and configured to eject fine liquid droplets of the organic material. The flash deposition apparatus can further include controller configured to control the pressure on the liquid of the organic material in the pressure controlled chamber. The liquid delivery system can include a liquid material delivering device that includes one or more transducers configured to eject the fine liquid droplets of the organic material from a liquid chamber. The flash deposition apparatus can further include a vacuum chamber which encloses the liquid delivery system, the heater, and the radiation shield. The liquid delivery system can produce fine liquid droplets of a mixture of organic materials. The organic materials can have different evaporation temperatures. The flash deposition apparatus can further include a transport mechanism configured to produce a relative between the substrate and the heater in a movement direction. The heater can have an elongated shape aligned perpendicular to the movement direction. The substrate can include a deposition surface aligned in a vertical direction, and wherein the heater is positioned on the side of the deposition surface. The substrate can include a deposition surface facing up in a horizontal direction, and wherein the heater is positioned above the deposition surface. The substrate can include a deposition surface facing down in a horizontal direction, and wherein the heater is positioned below the deposition surface.

These and other aspects, their implementations and other features are described in details in the drawings, the description and the claims.

### BRIEF DESCRIPTION OF THE DRAWINGS

FIG. 1 shows a conventional thermal evaporation deposition system.

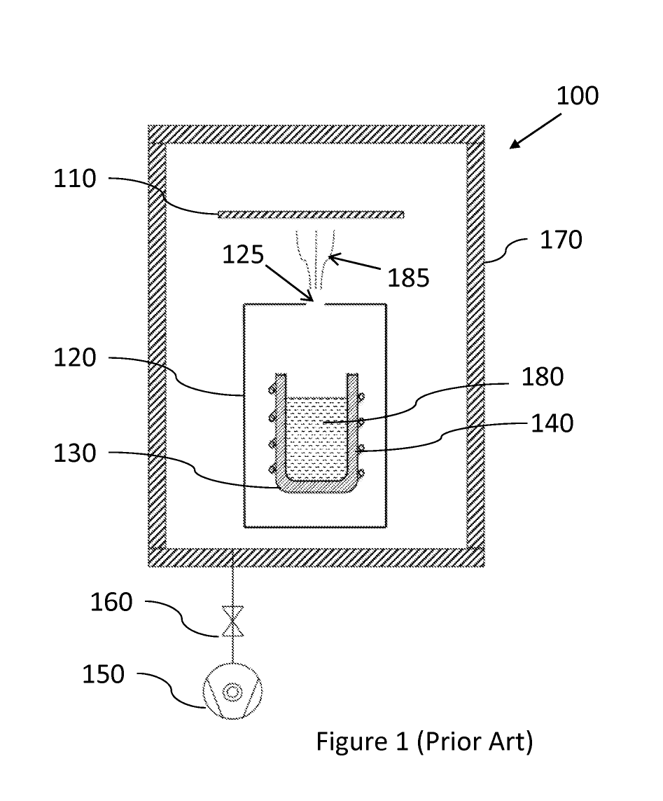

FIG. 2 is an exploded perspective view of a deposition apparatus in accordance with the present invention.

FIG. 3 is a top view of the evaporation heaters with nested radiation shields compatible with the deposition apparatus in FIG. 2.

FIG. 4 is a schematic diagram of an exemplified liquid material delivery system compatible with the deposition apparatus in FIG. 2.

FIGS. 5A-5D illustrate exemplified moving directions and positions of the substrates relative to respective deposition sources compatible with the disclosed deposition apparatus.

### DETAILED DESCRIPTION OF THE INVENTION

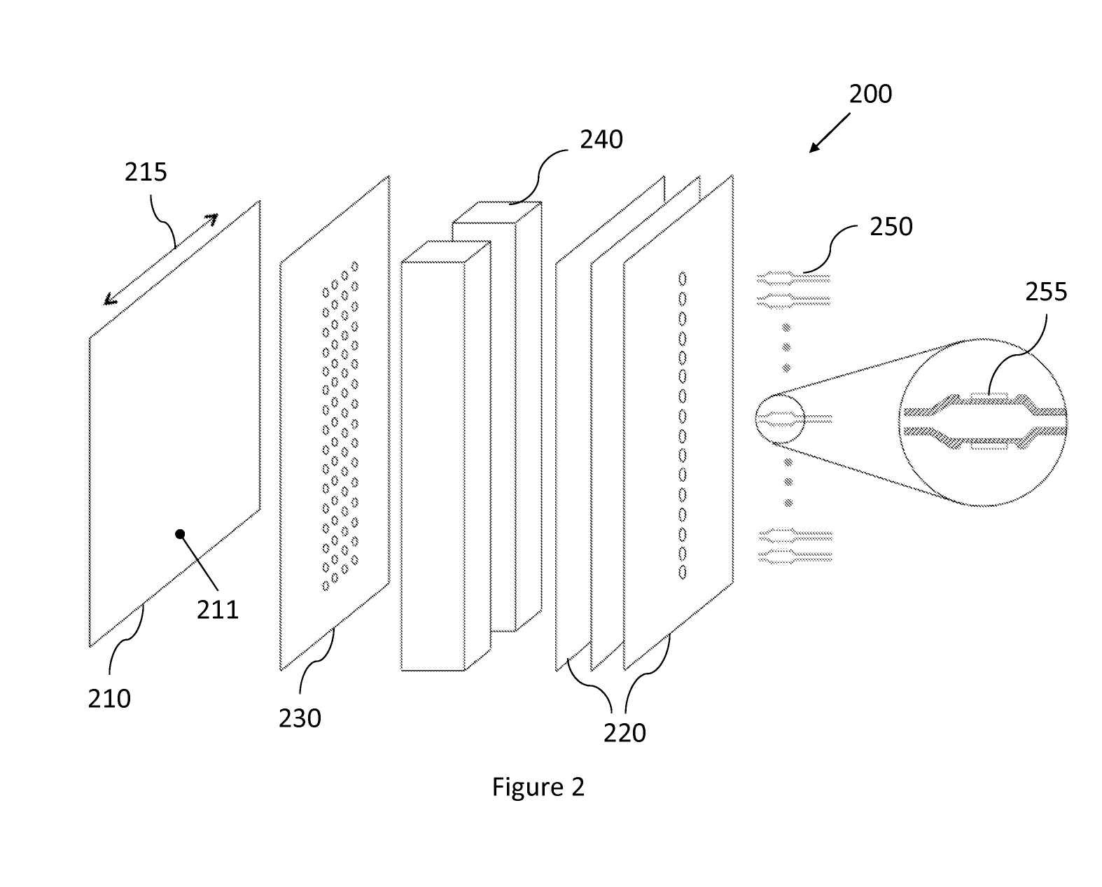

Referring to FIG. 2, a flash evaporation deposition apparatus 200 includes a substrate 210, a shower head 230, one or more evaporation heaters 240, one or more radiation shields 220, and liquid material delivering devices 250. Each of the liquid material delivering devices 250 can eject small liquid droplets on demand with precisely controlled volume and repeatability. The liquid droplets pass through the openings in the one or more radiation shields 220 to arrive at the vicinity of the evaporation heaters 240, wherein the liquid droplets are vaporized to produce a vapor. The vapor produced by the evaporation heaters 240 passes through the opening in the shower head 230 with plural openings. The shower head 230 ensures the vaporized materials to uniformly reach substrate 240 to form a thin film with defined distribution and desired deposition uniformity on the substrate 210. The thin film can be in liquid or solid phase, physically deposited or formed by chemical reactions. The substrate 210 can be moved along a direction 215 by a transport mechanism (not shown) to allow the evaporated materials to be deposited onto a deposition surface 211 of the substrate 210. Optionally, the substrate 210 can be chilled to a lower temperature to assist or accelerate the deposition process. Furthermore, the flash evaporation deposition apparatus 200 can be used in combination with subsequent process stations such as thermal curing or UV curing.

Each of the radiation shields 220 comprises a baffle and one or more holes in the baffle, wherein the one or more holes allow the fine liquid droplets to move freely to a vicinity of the heater 240.

An important function of the radiation shields 220 is to confine the heat generated by the evaporation heaters 240, and shield the heat from degrading the liquid materials before droplet ejections, or affecting the temperature and operations of the liquid material delivering devices 250. Another function of the radiation shields 220 is to minimize or prevent or block the vapor produced near the heaters 240 from migrating backwards to the liquid material delivering devices 250. The radiation shields 220 can be formed by multiple parallel baffles or plates configured in a nested manner to accomplish these functions.

The shower head 230 is configured to bring a uniform flux of vapor to the deposition surface 211 of the substrate 210, and also to prevent the heat generated by the one or more evaporation heaters 240 from impacting or interfering the temperature of the 210 substrate.

In some embodiments, the liquid material delivering devices 250 can include micro-pumps that are actuated by piezo-electric transducers 255. The piezo-electric transducer 255 can produce rapid pressure pulses in the liquid material in a chamber in response to electrical pulses, which results in ejections of liquid droplets out of a nozzle in the chamber. The droplet volume can be precisely controlled by frequency, voltages, durations and waveforms of the electric pulses as well as the viscoelastic properties of the liquid material in the chamber.

The liquid material delivering devices 250 can be disposed in different patterns such as a point source comprising one or more fluid pumps, or distributed in a one-dimensional or two-dimensional array, a circle, or a planar area (e.g. rectangular or round). The number of micro-pumps can be selected to provide the desired delivery rate of liquid material and to control deposition rate on the substrate 210. The distribution of micro-pumps is selected to match substrate size and shape to provide appropriate vapor distribution. The droplet ejection frequency can be in a range of 100 Hz −10,000 Hz, which can be controlled by varying the frequency of the electric pulses applied to the piezo-electric transducer. Ejection frequency selection and the electric pulse controls can be determined by the density and viscoelastic properties of the liquid material.

Examples of the liquid material include monomers, oligomers, precursors, polymers and mixtures of two or more types of materials. Furthermore, the liquid material can retain a liquid form at room temperature, or at an elevated temperature (e.g. with assisted heating at the nozzle or in the reservoir). Formulation parameters for the liquid material include composition, viscosity, surface tension, vapor pressure, density, etc. The droplet size can range 0.1-1000 μm in diameter, which depends on orifice size of the nozzle as well as driving pulse's waveform and frequency applied on the piezo-electric transducer. Furthermore, the properties of the liquid material such as density, viscosity, surface tension, etc. also affect droplet size. The droplet size can affect deposition performance including deposition rate, thin film thickness, uniformity, etc. Other exemplified mechanisms of the liquid material delivering device include solenoid valve metering, syringe pumping, and ultrasonic spraying technologies. Optionally, a heater can be mounted on the nozzle to instantaneously heat the organic materials to an elevated temperature and significantly lower their viscosities and thus to successfully eject materials with high viscosities; or the liquid materials in reservoir can be heated to a relatively high temperature (below evaporation temperature and below decomposing or degrading temperature) to assist material ejection.

Still referring to FIG. 2, the one or more evaporation heaters 240 can rapidly heat up liquid material droplets passing by or impinging on the heaters 240, and instantaneously transform the liquid material into a uniform vapor. The evaporation heaters 240 can be configured in different shapes such as plate, cuboid, cylinder, sphere, circular disk, etc., to match the configurations of the liquid material delivering devices 250. In some embodiments, the evaporation heater 240 can be implemented by an enclosed metal structure filled with oil (i.e. “an oil bath”) that is chemically stable in the high temperature environment. With its significantly large heat capacity, such enclosed “oil bath” can provide a stable heating environment since small droplets of liquid materials can hardly affect its surface temperature. Moreover, the evaporation heaters 240 can evaporate liquid materials instantaneously and create uniform material vapor since the material droplets are quite small and require little heating power to evaporate. The very short evaporation time also allows non-equilibrium evaporation of a mixture of materials with different evaporation temperatures. For simplicity, details of the “oil bath” heater are not shown in FIG. 2. Each rectangular evaporation heater is an enclosed metal structure filled with large quantity of oil to provide the evaporation heater a steady and uniform temperature environment. The surfaces in between two evaporation heaters serve as “hot plates” to flash evaporate liquid material flying by or impinging on. In the presently disclosed deposition system, only a small amount of liquid material is delivered, in the form of fine droplets, near or on the “hot plates”. Since it takes only a small amount of thermal power to heat and evaporate the liquid droplets, the droplets can be vaporized instantaneously and uniformly without prolonged heating or temperature fluctuations, which are experienced in conventional crucible-based deposition systems as previously described in the background in this disclosure. Thus, the disclosed system and method can provide better control of liquid delivery, more uniform vapor, and thus better controlled and more uniform thin film deposition on the substrate.

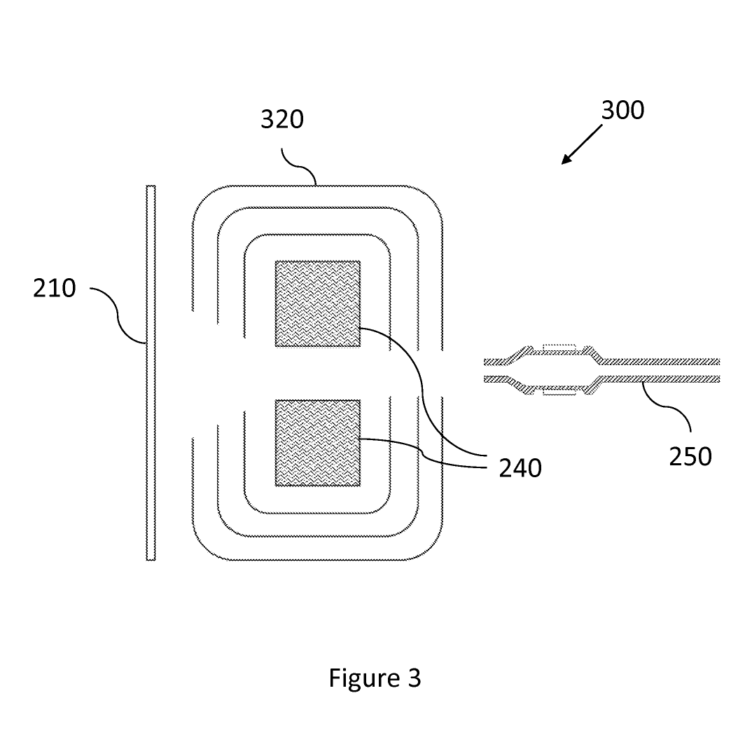

The radiation shields can be implemented in different shapes and configurations. In some embodiments, FIG. 3 illustrates another flash evaporation deposition apparatus 300 that includes nested enclosure walls 320 compatible with the disclosed evaporation deposition apparatus (such as the flash evaporation deposition apparatus 200 in FIG. 2). The nested enclosure walls 320 at least partially shield the heaters 240 from the substrate 210 and the liquid material delivering devices 250. The nested enclosure walls 320 can include several nested enclosures that partially enclose the evaporation heaters 240 and their immediate surrounding heating-evaporation region. Openings in the enclosure walls 320 allow ejected liquid droplets from the liquid material delivering device 250 to pass through. Other openings in the nested enclosure walls 320 allow vapor material to exit and flux toward the substrate 210.

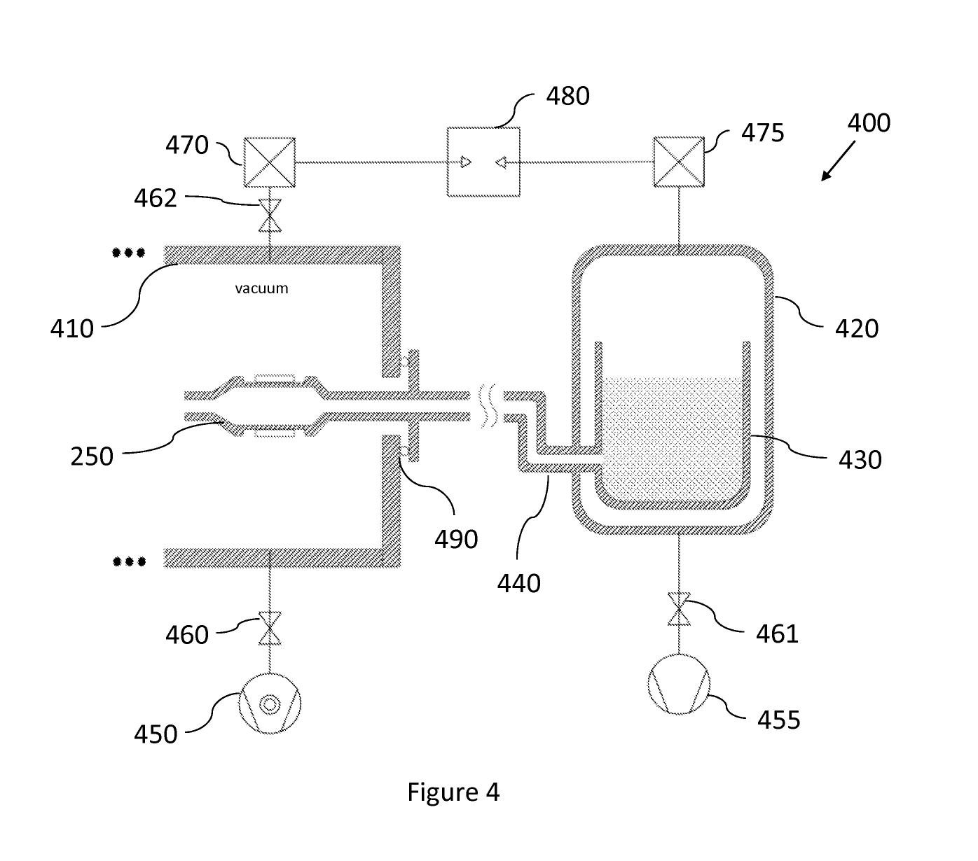

Referring to FIG. 4, a liquid material delivery system 400 includes a deposition chamber 410 and a pressure-controlled chamber 420 compatible with the disclosed flash evaporation deposition apparatus. A liquid material delivering device 250 in a deposition chamber 410 is connected, through a pipeline 440, to a reservoir 430 that is enclosed in the pressure-controlled chamber 420. The reservoir 430 is configured to contain a liquid material to be used for deposition. A turbo pump 450 regulated by a valve 460 produces vacuum in the deposition chamber 410. The interior pressure of the chamber 420 is controlled by a roughing pump 455 and a valve 461 to assist operation of liquid material delivering device 250. Moreover, the liquid material delivery system 400 can include vacuum gauges 470 and 475, and optionally a valve 462, and a programmable logic controller (PLC) 480 to monitor and control pressures in the deposition chamber 410 and the pressure-controlled chamber 420. One or more compressed O-rings 490 can be used to maintain the vacuum level in the deposition chamber 410. Optionally, the temperature of the reservoir 430 is controlled by resistive heater or active cooling subsystem (not shown) to provide the liquid material with optimized physical properties such as viscosity, surface tension, vapor pressure, etc.

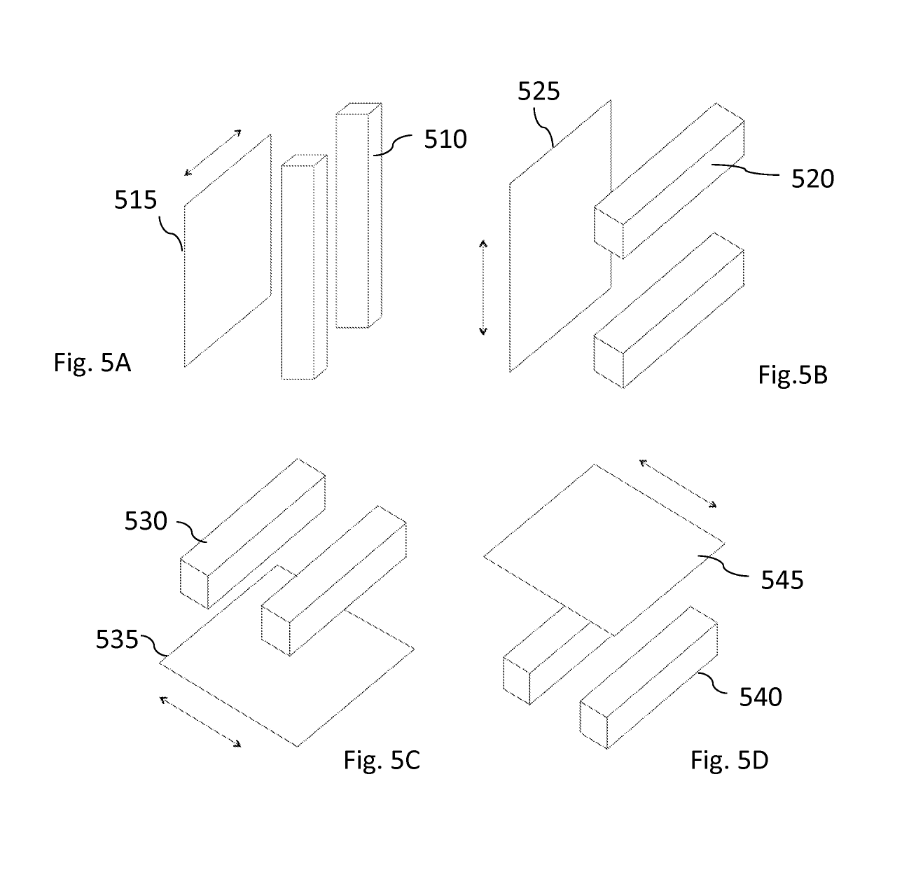

The presently disclosed deposition systems are compatible with different spatial configurations in terms of relations among the substrate, the deposition source, and substrate movement directions, which can be varied to meet the requirements of different applications. Referring to FIGS. 5A-5D, substrates 515, 525, 535, 545 are shown to be disposed in different positions and moving directions relative to their respective evaporation heaters 510, 520, 530, 540. In FIG. 5A, the substrate 515 is positioned with a deposition surface in a vertical orientation and the heaters 510 on the side of the deposition surface while the substrate 515 can move in a horizontal direction. In FIG. 5B, the substrate 525 is positioned with a deposition surface in a vertical orientation and the heaters 520 on the side of the deposition surface while the substrate 525 can move in a vertical direction. In FIG. 5C, the substrate 535 is positioned with a horizontal deposition surface facing up and the heaters 530 above the deposition surface while the substrate 535 can move in a horizontal direction. In FIG. 5D, the substrate 545 is positioned with a horizontal deposition surface facing down and the heaters 540 below the deposition surface while the substrate 545 can move in a horizontal direction. In the above configurations, the heater 510, 520, 530, or 540 can have an elongated shape aligned perpendicular to the movement direction so that the heaters can scan the respective substrate 515, 525, 535, or 545 to provide uniform material deposition over the entire substrate in consideration.

Only a few examples and implementations are described. Other implementations, variations, modifications and enhancements to the described examples and implementations may be made without deviating from the spirit of the present invention. For example, the disclosed deposition apparatus is compatible with other relative spatial configurations for the substrate, the deposition source, and substrate movement directions than the examples provided above. Moreover, the liquid delivery devices can be based on other mechanisms than the examples given above. Furthermore, the heaters in the disclosed deposition apparatus can be separated from the liquid delivery chamber by radiation shields in other configurations than the examples given above. The shower head can also be implemented in other configurations without deviating from the spirit of the present invention.

What is claimed is:

1. A flash deposition apparatus, comprising:
a liquid delivery system configured to produce fine liquid droplets of an organic material;
a heater configured to vaporize the fine liquid droplets to produce a vapor material to be directed to a substrate on which the organic material is deposited; and
a radiation shield configured to shield the heater from the liquid delivery system.

2. The flash deposition apparatus of claim 1, wherein the radiation shield comprises a baffle and one or more holes in the baffle, wherein the one or more holes are configured to allow the fine liquid droplets to move to a vicinity of the heater.

3. The flash deposition apparatus of claim 2, wherein the radiation shield is configured to block migration of the vapor material toward the liquid delivery system.

4. The flash deposition apparatus of claim 2, wherein the radiation shield comprises nested enclosure walls which shield the heater at least partially from the liquid delivery system.

5. The flash deposition apparatus of claim 4, wherein the nested enclosure walls shield the heater at least partially from the substrate.

6. The flash deposition apparatus of claim 1, wherein the radiation shield comprises multiple parallel baffles each comprising one or more holes configured to allow the fine liquid droplets to move to a vicinity of the heater.

7. The flash deposition apparatus of claim 1, further comprising:
a shower head comprising a plurality of holes configured to direct the vapor material to the substrate.

8. The flash deposition apparatus of claim 1, wherein the heater comprises an oil bath heated at a predetermined elevated temperature.

9. The flash deposition apparatus of claim 1, wherein the liquid delivery system comprises:
a pressure controlled chamber;
a reservoir in the pressure controlled chamber and configured to contain a liquid of the organic material; and
a liquid material delivering device in fluidic communication with the reservoir and configured to eject fine liquid droplets of the organic material.

10. The flash deposition apparatus of claim 9, further comprising:
controller configured to control the pressure on the liquid of the organic material in the pressure controlled chamber.

11. The flash deposition apparatus of claim 1, wherein the liquid delivery system comprises a liquid material delivering device that includes one or more transducers configured to eject the fine liquid droplets of the organic material from a liquid chamber.

12. The flash deposition apparatus of claim 1, further comprising:
a vacuum chamber which encloses the liquid delivery system, the heater, and the radiation shield.

13. The flash deposition apparatus of claim 1, wherein the liquid delivery system is configured to produce fine liquid droplets of a mixture of organic materials.

14. The flash deposition apparatus of claim 13, wherein the organic materials have different evaporation temperatures.

15. The flash deposition apparatus of claim 1, further comprising:
a transport mechanism configured to produce a relative between the substrate and the heater in a movement direction.

16. The flash deposition apparatus of claim 15, wherein the heater has an elongated shape aligned perpendicular to the movement direction.

17. The flash deposition apparatus of claim 1, wherein the substrate comprises a deposition surface aligned in a vertical direction, and wherein the heater is positioned on the side of the deposition surface.

18. The flash deposition apparatus of claim 1, wherein the substrate comprises a deposition surface facing up in a horizontal direction, and wherein the heater is positioned above the deposition surface.

19. The flash deposition apparatus of claim 1, wherein the substrate comprises a deposition surface facing down in a horizontal direction, and wherein the heater is positioned below the deposition surface.
